(19) United States
(12) Patent Application Publication
(10) Pub. No.: US 2005/0247471 A1
(43) Pub. Date: Nov. 10, 2005

(54) Electromagnetic shield using meta-material

(75) Inventors: Bruce R. Archambeault, Four Oaks, NC (US); Samuel R. Connor, Durham, NC (US)

Correspondence Address: SAWYER LAW GROUP LLP, PO BOX 51418, PALO ALTO, CA, 94303, US

(73) Assignee: International Business Machines Corporation, Armonk, NY (US)

(21) Appl. No.: 10/842,268

(22) Filed: May 10, 2004

(51) Int. Cl. H05K 9/00

(52) U.S. Cl. 174/35 MS

(57) ABSTRACT

An improved electromagnetic field shielding for electronic equipment is disclosed. The improved shielding is composed of meta-material, where the meta-material provides electromagnetic wave protection. The meta-material can be coupled to existing enclosures for electronic equipment. The meta-material provides a wideband negative permittivity or a wideband negative permeability, where a direction of propagation of incoming electromagnetic energy is reversed before the energy can induce currents on a surface of the enclosure. Enclosures with poor shielding protection can be used in conjunction with the improved shielding. The improved shielding thus provides protection against external electromagnetic fields without the need for apertures or tightly sealed seams.

### FIELD OF THE INVENTION

The present invention relates to electromagnetic field shielding, and more particularly to the utilization of meta-materials for electromagnetic field shielding.

### BACKGROUND OF THE INVENTION

Typically, protection against external electromagnetic threats to a computer system, or other electronic equipment, uses metal enclosures, cabinets, etc. These enclosures must have small openings or apertures, so that little or no electromagnetic energy propagates into the enclosure and disrupts the electronic equipment. Traditional shielded enclosures stop electromagnetic fields by using solid metal surfaces to enclose the equipment to be protected. The metal surface converts the electromagnetic energy into a surface current. As this current flows across the surface of the enclosure, if any obstructions (openings, apertures, slots, etc.) are encountered, then the current must flow around the obstruction. The added path length as the current flows around the obstruction causes a voltage difference across the aperture, etc., which in turn, creates a field on the opposite side of the aperture. Thus, the electromagnetic energy has “leaked” into the enclosure. Therefore, the apertures must be kept very small, compared to the wavelengths to protect against, so that the current does not have to travel a significant distance around the aperture. One drawback of this solution is that small openings in the enclosure are incompatible with airflow/cooling requirements, which presents a trade-off situation. Also, seams of the enclosures must be tightly sealed to prevent wide openings.

Accordingly, there exists a need for an improved electromagnetic field shielding for electronic equipment. The improved shielding should provide protection against external electromagnetic fields without the need for apertures or tightly sealed seams. The present invention addresses such a need.

### SUMMARY OF THE INVENTION

The improved shielding is composed of meta-material, where the meta-material provides electromagnetic wave protection. The meta-material can be coupled to existing enclosures for electronic equipment. The meta-material provides a wideband negative permittivity or wideband negative permeability, where a direction of propagation of incoming electromagnetic energy is reversed before the energy can induce currents on a surface of the enclosure. Enclosures with poor shielding protection can be used in conjunction with the improved shielding. The improved shielding thus provides protection against external electromagnetic fields without the need for apertures or tightly sealed seams.

### BRIEF DESCRIPTION OF THE FIGURES

FIG. 1 is a flowchart illustrating a method for providing electromagnetic field shielding for electronic equipment in accordance with the present invention.

FIGS. 2A and 2B illustrate the utilization of meta-material panels to provide electromagnetic field shielding for electronic equipment in accordance with the present invention.

### DETAILED DESCRIPTION

The present invention provides an improved electromagnetic field shielding for electronic equipment. The following description is presented to enable one of ordinary skill in the art to make and use the invention and is provided in the context of a patent application and its requirements. Various modifications to the preferred embodiment will be readily apparent to those skilled in the art and the generic principles herein may be applied to other embodiments. Thus, the present invention is not intended to be limited to the embodiment shown but is to be accorded the widest scope consistent with the principles and features described herein.

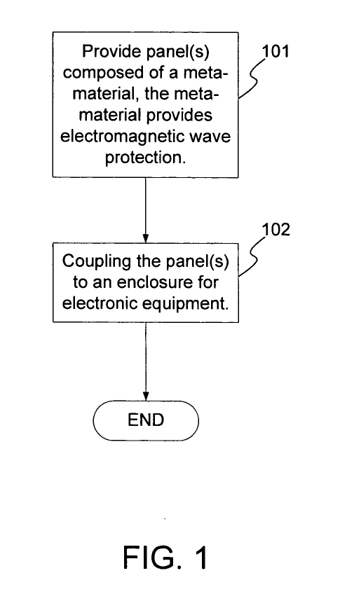

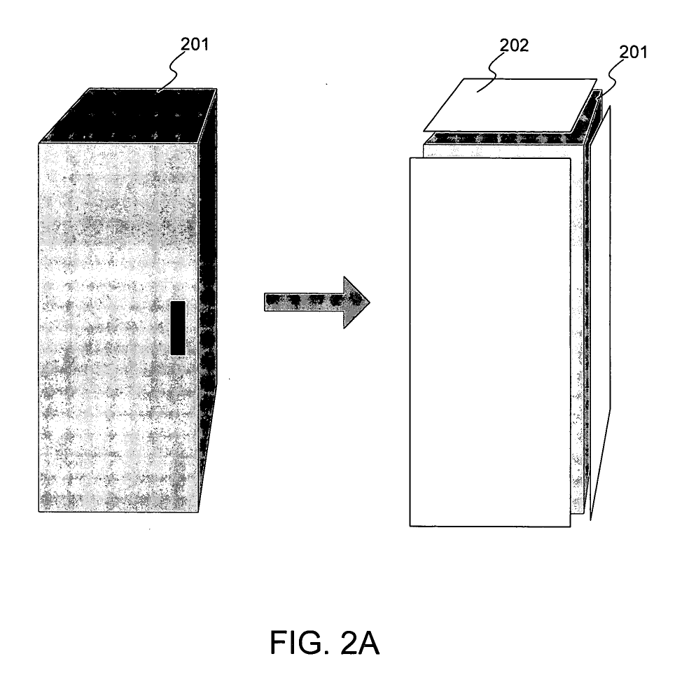

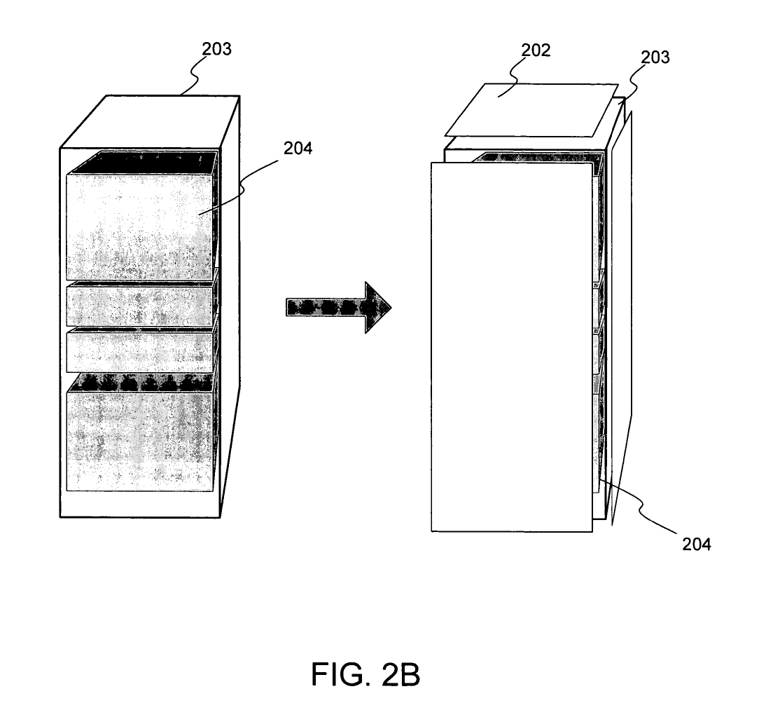

To more particularly describe the features of the present invention, please refer to FIGS. 1 through 2B in conjunction with the discussion below.

The present invention utilizes meta-materials to divert the electromagnetic energy from the enclosure for electronic equipment by not allowing currents to form on the surface of the enclosure. The meta-materials are composites designed to provide a wideband negative permittivity or a wideband negative permeability, which will reverse the direction of propagation (or reflect the incoming electromagnetic energy) before this energy can induce currents on the surface of the enclosure. Therefore, the restriction on shielded enclosures to have very small openings or apertures is no longer a concern, since the current is never induced on the surface of the enclosure.

FIG. 1 is a flowchart illustrating a method for providing electromagnetic field shielding for electronic equipment in accordance with the present invention. First, panel(s) composed of a meta-material is provided, where the meta-material provides electromagnetic wave protection, via step 101. The panel(s) is then coupled to an enclosure for the electronic equipment, via step 102.

For example, FIGS. 2A and 2B illustrate the utilization of meta-material panels to provide electromagnetic field shielding for electronic equipment in accordance with the present invention. FIG. 2A illustrates a conventional enclosure 201 in the left diagram for housing electronic equipment. In accordance with the present invention, illustrated in the right diagram, panels 202 composed of meta-materials are coupled to the enclosure 201 at its various sides. The panels 202 divert electromagnetic energy from the enclosure 201 as described above, providing an effective negative permittivity or negative permeability. FIG. 2B illustrates another conventional enclosure 203 in the left diagram, where the electronic equipment are placed inside the enclosure 203 in rack-mounted, individually shielded boxes 204. In accordance with the present invention, illustrated in the right diagram, the panels 202 are coupled to the enclosure 203 at its various sides, providing electromagnetic shielding in the same manner as in FIG. 2A.

Since the shielding is provided by the panels 202, the shielding provided by the enclosures (201, 203, or 204) is not important to the protection of the internal electronic equipment. Thus, metal-material panels 202 can be used in conjunction with conventional enclosures with typically poor shielding protection. This approach provides more reliable electromagnetic field shielding. It is particularly useful in upgrading existing systems, since the panels 202 can be coupled to existing enclosures.

An improved electromagnetic field shielding for electronic equipment has been disclosed. The improved shielding is composed of meta-material, where the meta-material provides electromagnetic wave protection. The meta-material can be coupled to existing enclosures for electronic equipment. The meta-material provides a wideband negative permittivity or a wideband negative permeability, where a direction of propagation of incoming electromagnetic energy is reversed before the energy can induce currents on a surface of the enclosure. Enclosures with poor shielding protection can be used in conjunction with the improved shielding. The improved shielding thus provides protection against external electromagnetic fields without the need for apertures or tightly sealed seams.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

1. An electromagnetic field shielding, comprising:
an enclosure for electronic equipment; and
at least one panel composed of a meta-material coupled to the enclosure, wherein the meta-material provides electromagnetic wave protection for the electronic equipment.

2. The shielding of claim 1, wherein the meta-material provides a wideband negative permittivity or a wideband negative permeability.

3. The shielding of claim 2, wherein a direction of propagation of incoming electromagnetic energy is reversed before the energy can induce currents on a surface of the enclosure.

4. The shielding of claim 1, wherein the enclosure has no openings.

5. A method for providing electromagnetic field shielding, comprising:
(a) providing at least one panel composed of a meta-material, wherein the meta-material provides electromagnetic wave protection; and
(b) coupling the at least one panel to an enclosure for electronic equipment.

6. The method of claim 5, wherein meta-material provides a wideband negative permittivity or a wideband negative permeability.

7. The method of claim 6, wherein a direction of propagation of incoming electromagnetic energy is reversed before the energy can induce currents on a surface of the enclosure.

8. The method of claim 5, wherein the enclosure has no openings.
